(19) United States
(12) Patent Application Publication
(10) Pub. No.: US 2022/0090258 A1
(43) Pub. Date: Mar. 24, 2022

(54) SUBSTRATE PROCESSING APPARATUS, METHOD OF MANUFACTURING SEMICONDUCTOR DEVICE AND NON-TRANSITORY TANGIBLE MEDIUM

(71) Applicant: KOKUSAI ELECTRIC CORPORATION, Tokyo (JP)

(72) Inventors: Yuji SAIKI, Toyama (JP); Tomoshi TANIYAMA, Toyama (JP); Akinori TANAKA, Toyama (JP)

(73) Assignee: KOKUSAI ELECTRIC CORPORATION, Tokyo (JP)

(21) Appl. No.: 17/479,531

(22) Filed: Sep. 20, 2021

(30) Foreign Application Priority Data
Sep. 23, 2020 (JP) 2020-159119

(51) Int. Cl. C23C 14/54; C23C 14/24

(52) U.S. Cl. CPC C23C 14/543; C23C 14/24

(57) ABSTRACT

Some embodiments of the present disclosure provide a technique capable of improving a film thickness uniformity on a surface of a substrate and between substrates. According to one or more embodiments, there is provided a technique that includes: a vaporizer configured to generate a source gas by vaporizing a liquid source; a tank in which the source gas ejected from the vaporizer is stored; a flow controller provided at a pipe connecting the vaporizer with the tank; a first valve provided at the pipe; a second valve provided downstream of the tank; a process chamber downstream of the second valve and to which the source gas is supplied; and a controller configured to be capable of controlling the first valve and the second valve to alternately and repeatedly perform accumulation of the source gas from the vaporizer into the tank and release of the source gas from the tank to the process chamber.

### CROSS-REFERENCE TO RELATED PATENT APPLICATION

This non-provisional U.S. patent application claims priority under 35 U.S.C. § 119 of Japanese Patent Application No. 2020-159119, filed on Sep. 23, 2020, in the Japanese Patent Office, the entire contents of which are hereby incorporated by reference.

### BACKGROUND

### 1. Field

The present disclosure relates to a substrate processing apparatus, a method of manufacturing a semiconductor device and a non-transitory tangible medium.

### 2. Related Art

Conventionally, as an example of a substrate processing apparatus, a semiconductor manufacturing apparatus capable of manufacturing a semiconductor device may be used. Further, according to some related arts, as an example of the semiconductor manufacturing apparatus, a vertical type apparatus capable of processing a plurality of substrates (hereinafter, also referred to as “wafers”) while the plurality of substrates are held (or accommodated) in a multistage manner along a vertical direction may be used.

In the vertical type apparatus described above, for example, a boat serving as a substrate retainer capable of holding (supporting or accommodating) the plurality of wafers in a multistage manner along the vertical direction is transferred (loaded) into a process chamber provided in a reaction tube while the plurality of wafers are accommodated in the boat. Then, for example, a substrate processing of forming a predetermined film on surfaces of the plurality of wafers is performed by injecting or filling the reaction tube with a chemical gas for forming the film and by processing the plurality of wafers at a predetermined temperature while controlling an inner temperature of the reaction tube. For example, a gas such as a source gas, a reactive gas and a carrier gas may be used as the chemical gas for forming the film. Further, in a film-forming process (that is, the substrate processing), in order to improve a step coverage of the wafer including a stepped portion such as a trench is formed on the surface thereof, for example, a “flush supply” of the source gas may be performed to adsorb the source gas on the surface of the wafer.

Recently, as the semiconductor device is miniaturized, a demand for a thickness uniformity of the film on the surface of the substrate and a demand for a thickness uniformity of the film between the plurality of substrates are increasing. However, conventionally, a flow rate of the source gas supplied from a vaporizer to a tank may not be accurately controlled. Therefore, a flow velocity of the source gas of the flush supply (also referred to as a “flush flow”or a “flash flow”) supplied from the tank to the process chamber may fluctuate. As a result, it is difficult to properly maintain the thickness uniformity of the film on the surface of the substrate and/or the thickness uniformity of the film between the plurality of substrates.

### SUMMARY

Some embodiments of the present disclosure provide a technique capable of improving a film thickness uniformity on a surface of a substrate and between a plurality of substrates.

According to one or more embodiments of the present disclosure, there is provided a technique that includes: a vaporizer configured to generate a source gas by vaporizing a liquid source supplied thereto; a tank in which the source gas ejected from the vaporizer is stored; a flow controller provided at a pipe connecting the vaporizer with the tank and configured to control a flow rate of the source gas supplied to the tank; a first valve provided at the pipe to open and close a flow path of the pipe; a second valve provided downstream of the tank to release the source gas accumulated in the tank; a process chamber provided downstream of the second valve and to which the source gas is supplied; and a controller configured to be capable of controlling the first valve and the second valve so as to alternately and repeatedly perform an accumulation of the source gas from the vaporizer into the tank and a release of the source gas from the tank to the process chamber.

### BRIEF DESCRIPTION OF THE DRAWINGS

FIG. 1 is a diagram schematically illustrating a vertical cross-section of a vertical type process furnace of a substrate processing apparatus according to one or more embodiments described herein.

FIG. 2 is a diagram schematically illustrating a horizontal cross-section taken along the line A-A of the vertical type process furnace of the substrate processing apparatus shown in FIG. 1.

FIG. 3 is a diagram schematically illustrating a part of the substrate processing apparatus according to the embodiments described herein.

FIG. 4 is a diagram schematically illustrating a configuration of a mass flow controller of the substrate processing apparatus according to the embodiments described herein.

FIG. 5 is a block diagram schematically illustrating a configuration of a controller and related components of the substrate processing apparatus according to the embodiments described herein.

FIG. 6 is a flowchart schematically illustrating a substrate processing according to the embodiments described herein.

FIG. 7 is a timing diagram schematically illustrating an example of a gas supply used in the substrate processing according to the embodiments described herein.

FIG. 8 is a graph schematically illustrating a change in an accumulation amount of a source gas in each of a first tank and a second tank with respect to a passage of time according to the embodiments described herein.

### DETAILED DESCRIPTION

### Embodiments

Hereinafter, one or more embodiments (also simply referred to as “embodiments”) according to the technique of the present disclosure will be described with reference to the drawings.

<Configuration of Substrate Processing Apparatus>

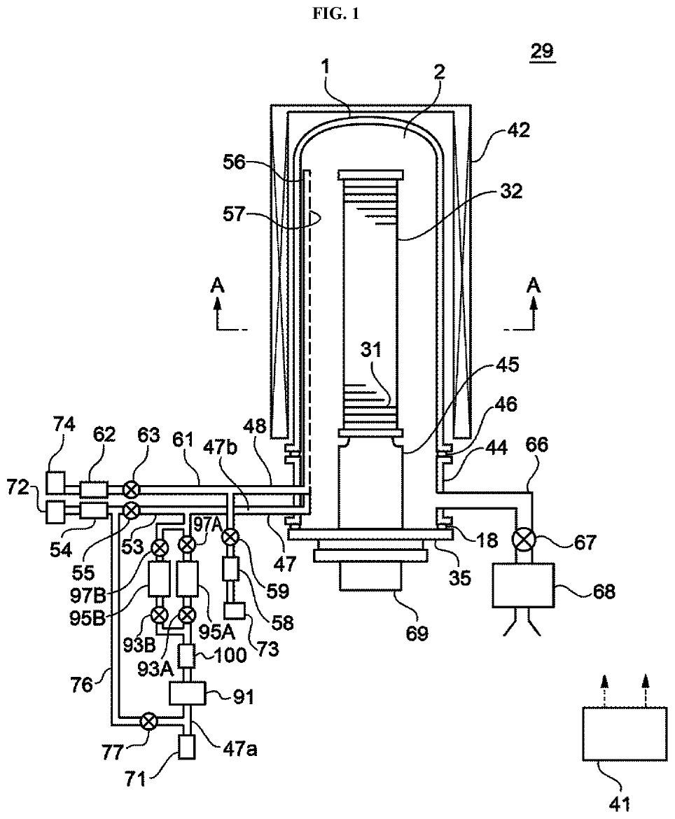

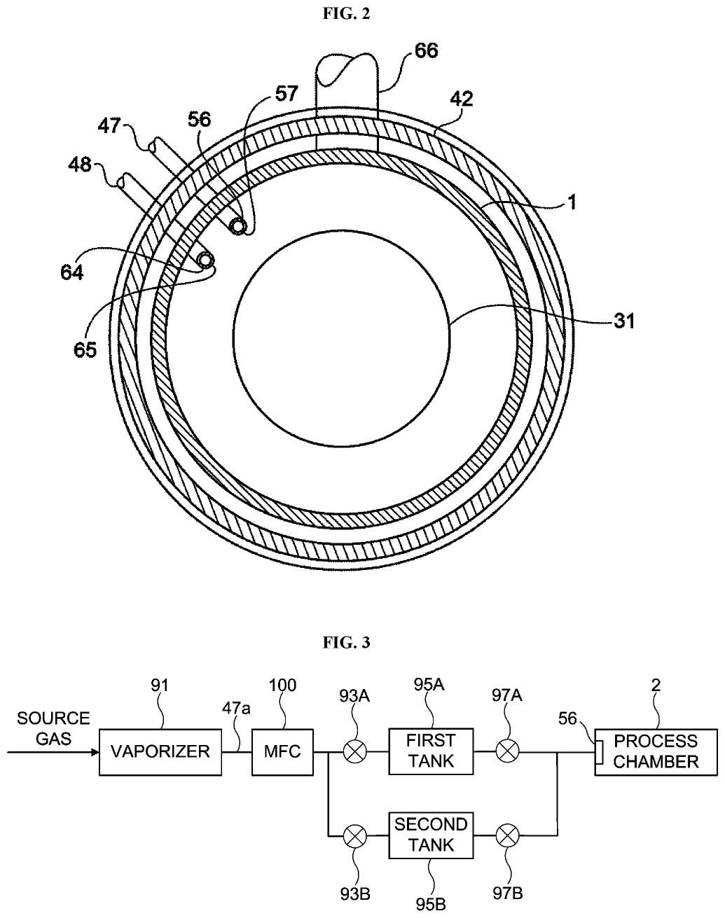

FIGS. 1 and 2 are diagrams schematically illustrating a vertical type process furnace (also simply referred to as a “process furnace”) 29 of a substrate processing apparatus which is an example of a processing apparatus according to the present embodiments. First, an outline of operations of the substrate processing apparatus to which the present embodiments are applied will be described with reference to FIG. 1. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

After a predetermined number of wafers to be processed including a wafer 31 are transferred and loaded (or charged) in a boat 32 serving as a substrate retainer, the boat 32 is elevated by a boat elevator (not shown), and the boat 32 is loaded into the process furnace 29. Hereinafter, the predetermined number of wafers (that is, a plurality of wafers) including the wafer 31 may also be simply referred to as wafers 31. When the boat 32 is completely loaded in the process furnace 29, the process furnace 29 is airtightly closed by a seal cap 35. In the process furnace 29 airtightly closed by the seal cap 35, the wafers 31 are heated, a process gas is supplied into the process furnace 29 in accordance with a selected process recipe, and an inner atmosphere of a process chamber 2 is exhausted by an exhauster (which is an exhaust system) (not shown) through a gas exhaust pipe 66. Thereby, the wafers 31 are processed.

Subsequently, the process furnace 29 will be described with reference to FIGS. 1 and 2. A reaction tube 1 is provided inside a heater 42 serving as a heating device (heating structure). A manifold 44 is provided at a lower end of the reaction tube 1 through an O-ring 46 which is an airtight seal, for example, made of a material such as stainless steel. A lower end opening (furnace opening) of the manifold 44 is hermetically closed by the seal cap 35 serving as a lid through an O-ring 18 which is an airtight seat The process chamber 2 is defined by at least the reaction tube 1, the manifold 44 and the seal cap 35.

The boat 32 is provided vertically on the seal cap 35 via a boat support 45, and the boat support 45 is made of a material capable of supporting the boat 32.

The process chamber 2 is provided with two gas supply pipes (that is, a first gas supply pipe 47 and a second gas supply pipe 48) serving as supply paths through which a plurality types of process gases (for example, two types of process gases) are supplied.

A liquid source supply source 71, a vaporizer 91 and a first mass flow controller 100 serving as a liquid flow rate controller (liquid flow rate control structure) are sequentially provided at the first gas supply pipe 47 in this order from an upstream side to a downstream side of the first gas supply pipe 47. Hereinafter, a mass flow controller is also referred to as an “MFC”. The first MFC 100 corresponds to a “flow controller” of the present embodiments. Two pipes are fluidically connected in parallel to a supply pipe 47a of the first gas supply pipe 47 on a downstream side of the first MFC 100. A first valve 93A and a second valve 97A, which are opening/closing valves, are provided at one of the two pipes; and a first valve 93B and a second valve 97B, which are opening/closing valves, are provided at the other one of the two pipes. Further, a first tank (which is a storage tank) 95A is provided between the first valve 93A and the second valve 97A, and a second tank 95B (which is a storage tank) is provided between the first valve 93B and the second valve 97B. According to the present embodiments, for example, the first MFC 100 is commonly used for the first tank 95A and the second tank 95B.

In particular, a first carrier gas supply pipe 53 through which a carrier gas is supplied is connected to downstream sides of the second valves 97A and 97B serving as gas supply valves. A carrier gas supply source 72, a second MFC 54 serving as a flow rate controller (flow rate control structure) and a valve 55 serving as an opening/closing valve are sequentially provided at the first carrier gas supply pipe 53 in this order from an upstream side to a downstream side of the first carrier gas supply pipe 53. Further, a first nozzle 56 is provided at a front end (tip) of the first gas supply pipe 47 from a lower portion to an upper portion along an inner wall of the reaction tube 1, and a plurality of first gas supply holes 57 through which a gas such as a source gas is supplied are provided at a side surface of the first nozzle 56. The plurality of first gas supply holes 57 are provided from a lower portion to an upper portion of the first nozzle 56. Each of the first gas supply holes 57 is provided at the same pitch, and an opening area of each of the first gas supply holes 57 is the same. The carrier gas (for example, N₂ gas), which is an inert gas supplied from the carrier gas supply source 72, can be supplied to the supply pipe 47a between the liquid source supply source 71 and the first MFC 100 through a valve 77 and a supply pipe 76.

In the description of the present embodiments, a portion of the first gas supply pipe 47 from the liquid source supply source 71 to the tanks (that is, the first tank 95A and the second tank 95B) is referred to as the “supply pipe 47a”. Further, a portion of the first gas supply pipe 47 from the tanks (that is, the first tank 95A and the second tank 95B) to the first nozzle 56 is referred to as a “supply pipe 47b”. A cross-sectional area of a flow path of the supply pipe 47b may be equal to or greater than a cross-sectional area of a flow path of the supply pipe 47a. It is preferable that a length and a conductance of the supply pipe 47b from the first tank 95A to the first nozzle 56 are equal to a length and a conductance of the supply pipe 47b from the second tank 95B to the first nozzle 56, respectively.

In the present embodiments, a first gas supplier (which is a first gas supply structure or a first gas supply line) is constituted mainly by the first gas supply pipe 47, the vaporizer 91, the first MFC 100, the first valves 93A and 93B, the first tank 95A, the second tank 95B and the second valves 97A and 97B. The first gas supplier may further include the first nozzle 56. The first gas supplier may further include the first carrier gas supply pipe 53, the second MFC 54 and the valve 55. In addition, the first gas supplier may further include the liquid source supply source 71 and the carrier gas supply source 72.

A reactive gas supply source 73, a third MFC 58 serving as a flow rate controller (flow rate control structure) and a valve 59 serving as an opening/closing valve are sequentially provided at the second gas supply pipe 48 in this order from an upstream side to a downstream side of the second gas supply pipe 48. A second carrier gas supply pipe 61 through which the carrier gas is supplied is connected to a downstream side of the valve 59. A carrier gas supply source 74, a fourth MFC 62 serving as a flow rate controller (flow rate control structure) and a valve 63 serving as an opening/closing valve are sequentially provided at the second carrier gas supply pipe 61 in this order from an upstream side to a downstream side of the second carrier gas supply pipe 61. Further, a second nozzle 64 is provided at a front end (tip) of the second gas supply pipe 48 in parallel with the first nozzle 56, and a plurality of second gas supply holes 65 through which a gas such as a reactive gas is supplied are provide at a side surface of the second nozzle 64. The plurality of second gas supply holes 65 are provided from a lower portion to an upper portion of the second nozzle 64. Each of the second gas supply holes 65 is provided at the same pitch, and an opening area of each of the second gas supply holes 65 is the same.

In the present embodiments, a second gas supplier (which is a second gas supply structure or a second gas supply line) is constituted mainly by the second gas supply pipe 48, the third MFC 58, the valve 59 and the second nozzle 64. The second gas supplier may further include the second carrier gas supply pipe 61, the fourth MFC 62 and the valve 63. In addition, the second gas supplier may further include the reactive gas supply source 73 and the carrier gas supply source 74.

A liquid source supplied from the liquid source supply source 71 is supplied into the first carrier gas supply pipe 53 through the vaporizer 91, the first MFC 100, the first valves 93A and 93B, the first tank 95A, the second tank 95B and the second valves 97A and 97B, and then is supplied into the process chamber 2 through the first nozzle 56. When the liquid source is supplied into the process chamber 2, the liquid source is supplied as the source gas which is obtained by vaporizing the liquid source by the vaporizer 91. In addition, the reactive gas supplied from the reactive gas supply source 73 is supplied into the second carrier gas supply pipe 61 through the third MFC 58 and the valve 59, and then is supplied into the process chamber 2 through the second nozzle 64. The supply pipe 76 and the valve 77 are used when purging the source gas from the first gas supplier.

The process chamber 2 is connected to a vacuum pump (also simply referred to as a “pump”) 68 serving as an exhaust apparatus (exhaust structure) via the gas exhaust pipe 66 through which the gas such as the source gas and the reactive gas is exhausted. The inner atmosphere of the process chamber 2 is vacuum-exhausted by the vacuum pump 68. By opening or closing a valve 67 serving as a pressure regulating valve (pressure adjusting valve), it is possible to vacuum-exhaust the process chamber 2 or to stop the vacuum exhaust. The pressure regulating valve may also be simply referred to as a “regulating valve”. In addition, by adjusting an opening degree of the valve 67, it is possible to adjust a pressure such as an inner pressure of the process chamber 2.

A boat rotator 69 is provided on the seal cap 35. The boat rotator 69 is configured to rotate the boat 32 in order to improve a uniformity of a processing such as a substrate processing described later.

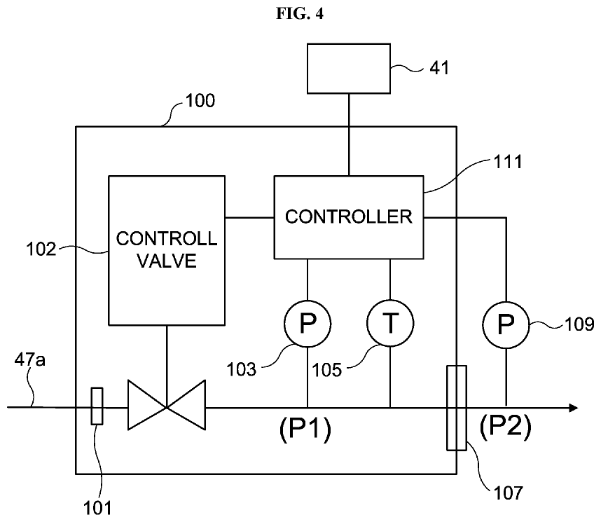

Subsequently, each configuration of the first gas supply line to be managed according to the present embodiments will be specifically described with reference to FIGS. 3 and 4. FIG. 3 is an enlarged view of a main part of the supply pipe 47a through which the source gas is supplied.

<Vaporizer>

The vaporizer 91 is configured to heat the liquid source supplied in a liquid state and to vaporize the liquid source to generate the source gas. For example, a chlorosilane-based gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas, hexachlorodisilane gas (Si₂Cl₆, abbreviated as HCDS) gas and octachlorotrisilane (Si₃Cl₈, abbreviated as OCTS) gas may be used as the source gas. For example, a fluorosilane-based gas such as tetrafluorosilane (SiF₄) gas and difluorosilane (SiH₂F₂) gas, a bromosilane-based gas such as tetrabromosilane (SiBr₄) gas and dibromosilane (SiH₂Br₂) gas, or an iodine silane-based gas such as tetraiodide silane (SiI₄) gas and diiodosilane (SiH₂I₂) gas may be used as the source gas. For example, an aminosilane-based gas such as tetrakis(dimethylamino)silane (Si[N(CH₃)₂]₄, abbreviated as 4DMAS) gas, tris(dimethylamino)silane (Si[N(CH₃)₂]₃H, abbreviated as 3DMAS) gas, bis(thethylamino)silane (Si[N(C₂H₅)₂]₂H₂, abbreviated as BDEAS) gas and bis(tertiarybutylamino) silane (SiH₂[NH(C₄H₉)]₂, abbreviated as BTBAS) gas may be used as the source gas. For example, an organic silane-based source gas such as tetraethoxysilane (Si(OC₂H₅)₄, abbreviated as TEOS) gas may be used as the source gas. One or more of the gases described above may be used as the source gas. That is, a source stored in a liquid state by being subject to pressurization or cooling may also be used as the source gas. Further, according to the present embodiments, the vaporizer 91 is configured to supply the source gas alone to the first tank 95A and the second tank 95B without supplying the carrier gas.

<Tank>

A volume of the first tank 95A is substantially equal to a volume of the second tank 95B. The source gas supplied from the vaporizer 91 is stored in the first tank 95A and the second tank 95B. According to the present embodiments, two tanks (that is, the first tank 95A and the second tank 95B) are provided in parallel, and the two tanks are alternately used to accumulate and release (i.e., discharge) the source gas.

While the present embodiments will be described in detail by way of an example in which the two tanks are provided, the number of tanks is not limited thereto. For example, three or more tanks may be appropriately used. When three or more tanks are used, a volume of each tank is substantially equal, and the three or more tanks are cyclically used to accumulate and release the source gas. Herein, the term “alternately” in the present specification may also refer to “cyclically”. Specifically, “three or more tanks are alternately used to accumulate and release the source gas” may refer to “three or more tank are cyclically used to accumulate and release the source gas”.

<First Valve and Second Valve>

The first valves 93A and 93B and the second valves 97A and 97B are provided at the first gas supply pipe 47 (that is, the supply pipe 47a and the supply pipe 47b). Flow paths of the first gas supply pipe 47 (that is, the flow path of the supply pipe 47a and the flow path of the supply pipe 47b) may be opened and closed by opening and closing the first valves 93A and 93B and the second valves 97A and 97B. The first valve 93A is provided on an upstream side of the first tank 95A, and the first valve 93B is provided an upstream side of the second tank 95B. By opening and closing the first valves 93A and 93B, it is possible to control an accumulation of the source gas in the first tank 95A and the second tank 95B. The second valve 97A is provided on a downstream side of the first tank 95A, and the second valve 97B is provided on a downstream side of the second tank 95B. By opening and closing the second valves 97A and 97B, it is possible to control a release of the source gas accumulated in the first tank 95A and the second tank 95B to the process chamber 2.

<First MFC>

As shown in FIG. 4, the first MFC 100 may include a pre-filter 101, a control valve 102, a first pressure sensor 103, a temperature sensor 105, an orifice 107, a second pressure sensor 109 and a controller 111. Although not shown, the first MFC 100 is provided with an opening/closing valve configured to open and close the flow paths of the first gas supply pipe 47 at a back end of the control valve 102.

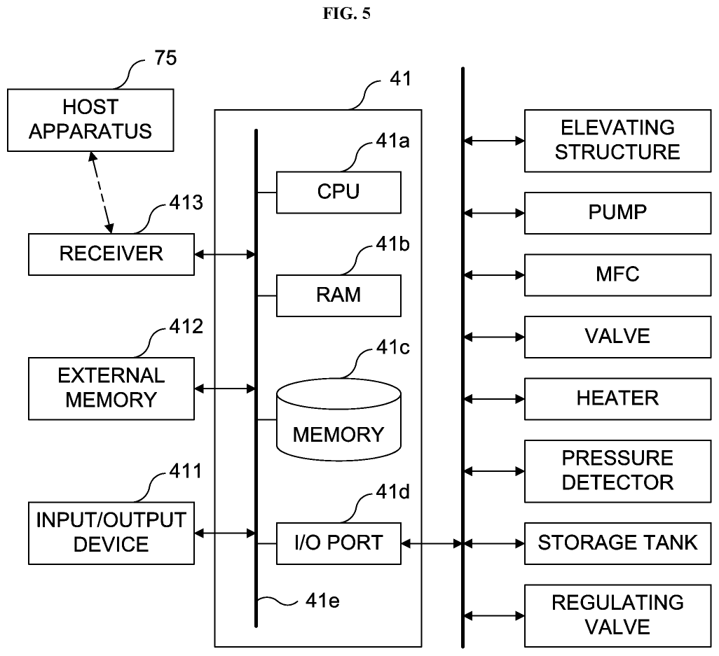

The first pressure sensor 103, the temperature sensor 105 and the second pressure sensor 109 are connected to the controller 111. In addition, the opening/closing valve (not shown), the first valves 93A and 93B and the second valves 97A and 97B are connected to the controller 111. Further, the controller 111 is connected to a controller 41 (also referred to as a “main controller”) described later (see FIG. 5). The controller 111 is configured to control (or adjust) a flow rate of the source gas flowing to the downstream side of the first gas supply pipe 47 (the supply pipe 47a) to a predetermined value, and is further configured to control the first valves 93A and 93B and the second valves 97A and 97B such that the accumulation of the source gas into the first tank 95A and the second tank 95B and the release of the source gas from the first tank 95A and the second tank 95B are alternately and repeatedly performed. While the present embodiments will be described in detail by way of an example in which the controller 111 and the controller 41 are provided separately, the present embodiments are not limited thereto. For example, the controller 111 and the controller 41 may be provided integrally as a single component.

For example, the first MFC 100 according to the present embodiments is a pressure control type MFC that utilizes a choked flow in an orifice such as the orifice 107. The first MFC 100 is configured to be able to maintain the flow rate of the source gas to the first tank 95A and the second tank 95B constant regardless of a pressure fluctuation of the vaporizer 91. Further, an accumulation time of the source gas into each of the first tank 95A and the second tank 95B and a flush period of the source gas therein are controlled such that an inner pressure of each of the first tank 95A and the second tank 95B maintains a pressure value that satisfies a choked flow condition in the orifice 107 in the first MFC 100. In this context, the term “flush supply” refers to an operation of supplying the gas such as the source gas at a high pressure and/or a large amount within a short time and “a flush period of the source gas” described above refers to a period of time while the source gas is flush supplied (i.e., subject to a flush supply).

Specifically, when a supply pressure of the source gas from the vaporizer 91 on an upstream side of the orifice 107 is “P 1” and an inner pressure of the tank (each of the first tank 95A and the second tank 95B) on a downstream side of the orifice 107 is “P2”, the inner pressure P2 is maintained at a pressure value that satisfies “P1≥2P2” which is a formula of the choked flow condition in the orifice 107.

As shown in FIG. 5, the substrate processing apparatus includes the controller 41 configured to control operations of components constituting the substrate processing apparatus.

The controller 41 is schematically illustrated in FIG. 5. The controller 41 serving as a control apparatus (control structure) is constituted by a computer including a CPU (Central Processing Unit) 41a, a RAM (Random Access Memory) 41b, a memory 41c and an I/O port 41d. The RAM 41b, the memory 41c and the I/O port 41d may exchange data with the CPU 41a through an internal bus 41e. For example, an input/output device 411 configured by a component such as a touch panel and an external memory 412 may be connected to the controller 41. Further, a receiver 413 connected to a host apparatus 75 via a network may be provided. The receiver 413 is configured to receive information on other apparatuses from the host apparatus 75.

The memory 41c is configured by components such as a flash memory and a hard disk drive (HDD). For example, a control program configured to control the operation of the substrate processing apparatus, a process recipe containing information on the sequences and conditions of the substrate processing described later, or a correction recipe may be readably stored in the memory 41c. The process recipe or the correction recipe is obtained by combining steps of the substrate processing described later performed in a substrate processing mode or steps of a characteristic confirmation processing such that the controller 41 can execute the steps to acquire a predetermined result, and functions as a program. Hereafter, the process recipe, the correction recipe and the control program may be collectively or individually referred to as a “program”. In the present specification, the term “program” may refer to the process recipe alone or the correction recipe alone, may refer to the control program alone, or may refer to a combination of the process recipe, the correction recipe and the control program. The RAM 41b functions as a memory area (work area) where a program or data read by the CPU 41a is temporarily stored.

The I/O port 41d is connected to the above-described components such as an elevating structure (for example, the boat elevator), the heater 42, the mass flow controllers described above and the valves described above.

The controller 41 serving as the control structure may be configured to control various operations of the components constituting the substrate processing apparatus, such as flow rate adjusting operations for various gases by the MFCs described above, opening/closing operations of the valves described above, a temperature adjusting operation by the heater 42, a start and stop of the vacuum pump 68, an operation of adjusting a rotation speed of the boat rotator 69, an elevating and lowering operation of the boat elevator and an operation of a pressure meter (not shown).

The first valves 93A and 93B and the second valves 97A and 97B of the first gas supply line to be managed according to the present embodiments are connected to the controller 41. The controller 41 corresponds to the “control structure” of the present embodiments. As described above, the controller 41 is configured to control the first valves 93A and 93B and the second valves 97A and 97B such that the accumulation of the source gas into the first tank 95A and the second tank 95B and the release of the source gas from the first tank 95A and the second tank 95B are alternately and repeatedly performed.

The controller 41 may be embodied by a dedicated computer or by a general-purpose computer. According to the present embodiments, for example, the controller 41 may be embodied by preparing the external memory 412 storing the program described above and by installing the program onto the general-purpose computer using the external memory 412. For example, the external memory 412 may include a semiconductor memory such as a USB memory and a memory card. A method of providing the program to the computer is not limited to the external memory 412. For example, the program may be supplied to the computer (general-purpose computer) using communication means such as the Internet and a dedicated line instead of the external memory 412. The memory 41c or the external memory 412 may be embodied by a non-transitory computer readable recording medium. Hereafter, the memory 41c and the external memory 412 may be collectively or individually referred to as a “recording medium”. In the present specification, the term “recording medium” may refer to the memory 41c alone, may refer to the external memory 412 alone or may refer to both of the memory 41c and the external memory 412.

<Substrate Processing Method (Substrate Processing)>

Hereinafter, an example of processing the substrate will be described. The present embodiments will be described by way of an example in which a cycle process of the substrate processing is performed as a part of a manufacturing process of a semiconductor device. For example, the cycle process serving as a film-forming process is performed by alternately supplying a source (that is, the source gas) and a reactant (that is, the reactive gas) to the process chamber 2. According to the present embodiments, an example of forming a silicon nitride film (Si₃N₄ film, hereinafter also referred to as an “SiN film”) on the substrate (that is, the wafer 31) by using a silicon source gas serving as the source and a nitrogen-containing gas serving as the reactant will be described.

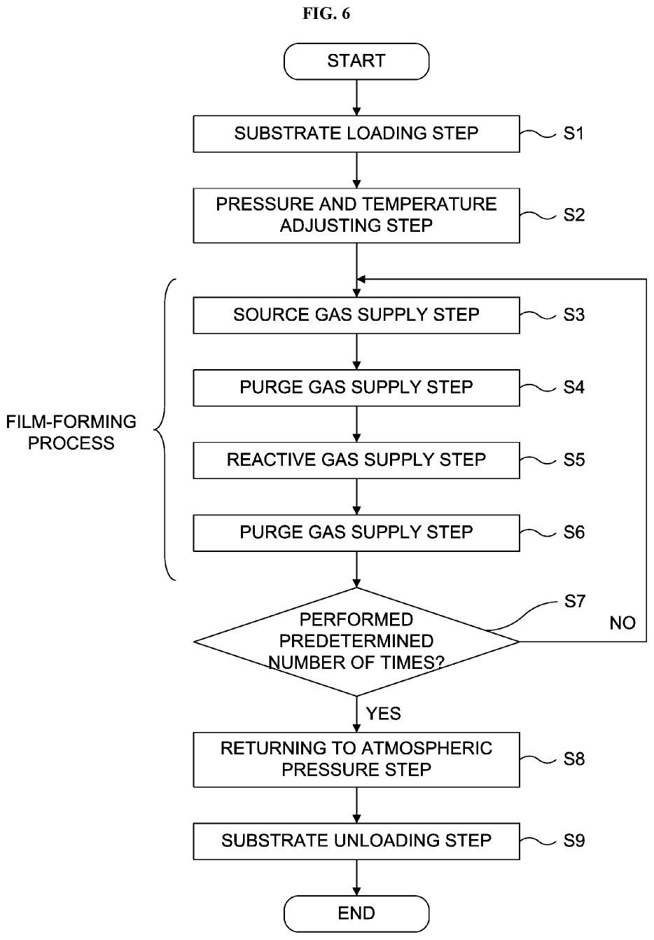

In the film-forming process of the substrate processing according to the present embodiments, the SiN film is formed on a surface of the wafer 31 by performing a cycle a predetermined number of times (at least once). For example, the cycle may include: a step of supplying the silicon source gas to the wafer 31 in the process chamber 2 (a first step of the film-forming process, a step S3 in FIG. 6); a purge step of removing the source gas (residual gas) from the process chamber 2 (a second step of the film-forming process, a step S4 in FIG. 6); a step of supplying the nitrogen-containing gas to the wafer 31 in the process chamber 2 (a third step of the film-forming process, a step S5 in FIG. 6); and a purge step of removing the nitrogen-containing gas (residual gas) from the process chamber 2 (a fourth step of the film-forming process, a step S6 in FIG. 6). The steps S3, S4, S5 and S6 of the cycle are non-simultaneously performed.

First, as described above, the wafers 31 are charged (transferred) into the boat 32, and the boat 32 is loaded (transferred) into the process chamber 2 (a step Si in FIG. 6). When the step Si is performed, the first tank 95A and the second tank 95B are connected to the liquid source supply source 71, as shown in FIG. 1. After the boat 32 is loaded into the process chamber 2, the inner pressure and an inner temperature of the process chamber 2 are adjusted (a step S2 in FIG. 6). Subsequently, the four steps of the film-forming process are sequentially performed. Each step of the film-forming process will be described in detail below.

<First Step of Film-Forming Process, Step S3>

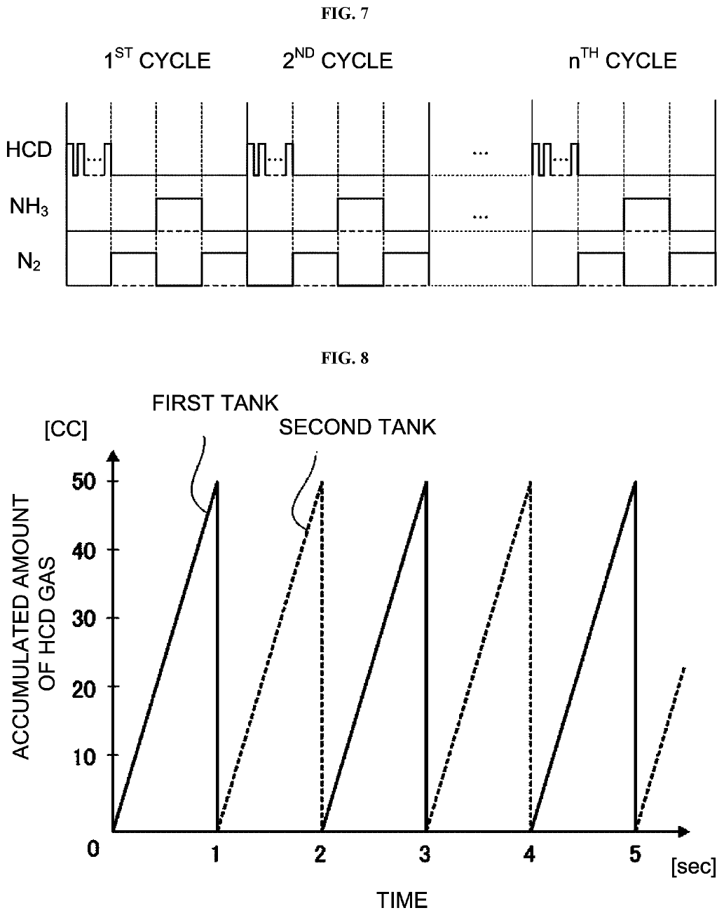

In the first step of the film-forming process, as shown in FIG. 7, first, the source gas is adsorbed on the surface of the wafer 31 by intermittently performing a flush supply of instantaneously (relatively shortly) releasing the source gas. In the present specification, the term “flush supply” refers to an operation of supplying the gas such as the source gas at a high pressure and/or a large amount within a short time. Specifically, in the first gas supply line, the first valve 93A on the upstream side of the first tank 95A is opened and the second valve 97A on the downstream side of the first tank 95A is closed so as to supply the source gas obtained by vaporizing the liquid source by the vaporizer 91 to the first tank 95A through the first MFC 100. An accumulation amount of the source gas supplied to the first tank 95A in the step S3 is illustrated by a solid diagonal line between 0 sec and 1 sec in FIG. 8. While the source gas is being supplied to the first tank 95A, the first valve 93B on the upstream side of the second tank 95B is closed so as to stop a supply of the source gas to the second tank 95B.

According to the present embodiments, the accumulation time of the source gas in the first tank 95A in the step S3 is determined so as to accumulate an amount of the source gas equal to or greater than a minimum amount of a single flush supply to be performed using the first tank 95A. Specifically, the accumulation time of the source gas in the first tank 95A is about 1 second, as shown in FIG. 8. Further, the flow rate of the source gas to be accumulated in the first tank 95A is set to a constant flow rate within a range from about 40 cc/sec to 50 cc/sec, which is equivalent to 3 slm when converted by the standard gas conversion flow rate. The accumulation time of the source gas in the first tank 95A is set to be equal to or longer than a time for the source gas to reach a predetermined accumulation amount at a constant flow rate.

When the predetermined amount of the source gas is accumulated in the first tank 95A, the first valve 93A on the upstream side of the first tank 95A is closed and the second valve 97A on the downstream side of the first tank 95A is opened so as to release and flush supply the source gas from the first tank 95A to the process chamber 2. The flush supply of the source gas is illustrated by a solid vertical line at 1 sec in FIG. 8. The source gas accumulated in the first tank 95A is released (or ejected) into the process chamber 2 in a decompressed state through the first nozzle 56 in a time shorter than the accumulation time of the source gas in the first tank 95A, and is flush supplied to the process chamber 2. The release of the source gas from the first tank 95A is instantaneously terminated, and after the release, the accumulation amount of the source gas in the first tank 95A becomes almost zero (0).

In the step S3, when the first valve 93A is closed or the supply (release) of the source gas from the first tank 95A is completed, almost simultaneously, the first valve 93B on the upstream side of the second tank 95B provided in parallel with the first tank 95A is opened and the second valve 97B on the downstream side of the second tank 95B is closed so as to supply the source gas to the second tank 95B. The accumulation amount of the source gas supplied to the second tank 95B in the step S3 is illustrated by a dashed diagonal line between 1 sec and 2 sec in FIG. 8. While the source gas is being supplied to the second tank 95B, the first valve 93A on the upstream side of the first tank 95A is closed so as to stop the supply of the source gas to the first tank 95A.

Similar to the accumulation time of the source gas in the first tank 95A in the step S3, an accumulation time of the source gas in the second tank 95B in the step S3 is determined so as to accumulate the amount of the source gas equal to or greater than the minimum amount of a single flush supply to be performed using the second tank 95B. Specifically, the accumulation time of the source gas in the second tank 95B is about 1 second, as shown in FIG. 8. Further, the flow rate of the source gas to be accumulated in the second tank 95B is set to the constant flow rate within the range from about 40 cc/sec to 50 cc/sec, which is equivalent to 3 slm when converted by the standard gas conversion flow rate. Similar to the accumulation time of the source gas in the first tank 95A, the accumulation time of the source gas in the second tank 95B is set to be equal to or longer than the time for the source gas to reach the predetermined accumulation amount at the constant flow rate.

When the predetermined amount of the source gas is accumulated in the second tank 95B, the first valve 93B on the upstream side of the second tank 95B is closed and the second valve 97B on the downstream side of the second tank 95B is opened so as to release and flush supply the source gas from the second tank 95B to the process chamber 2. The source gas accumulated in the second tank 95B is released (or ejected) into the process chamber 2 in the decompressed state through the first nozzle 56 in a time shorter than the accumulation time of the source gas in the second tank 95B, and is flush supplied to the process chamber 2. The release of the source gas from the second tank 95B is instantaneously terminated, and after the release, the accumulation amount of the source gas in the second tank 95B becomes almost zero (0).

Then, the source gas is repeatedly flush supplied by alternately and repeatedly performing the same operations of the first tank 95A and the second tank 95B described above. According to the present embodiments, for example, the flush period is about 1 second, and the source gas of about 50 cc is released (supplied) in each flush supply. According to the present embodiments, by repeatedly performing the accumulation (filling) of the source gas into the first tank 95A and the second tank 95B and the release of the source gas from the first tank 95A and the second tank 95B and by alternately using the first tank 95A and the second tank 95B, it is possible to flush supply the source gas whose flow rate is high when the source gas is released. Thereby, a flow velocity of the source gas on the surface of the wafer 31 can be made equal to or higher than a specific flow velocity capable of facilitating a gas exchange with a space in a trench of the wafer 31. As a result of repeatedly performing the flush supply of the source gas with a high flow velocity, it is possible to distribute the source gas to the entire surface of the wafer 31 including an inside of a portion such as the trench in a short time of several seconds. The flow velocity of the source gas on the surface of the wafer 31 in the step S3 depends on parameters such as the amount of the source gas accumulated in the tank such as the first tank 95A and the second tank 95B (or a pressure of the source gas), a volume of the tank and a shape and size of the supply pipe 47b and a shape and size of each of the first gas supply holes 57. However, the parameters described above basically do not change. Therefore, when the accumulation amount remains the same, the flow velocity of the source gas corresponding to the same pulse waveform can be achieved each time. Further, since the flush supply of the source gas is performed through the same first nozzle 56 each time, the same gas flow can be formed in the process chamber 2 when the flush period is constant or the inner pressure of the process chamber 2 immediately before the flush supply is sufficiently low.

The release of the source gas from each tank is not limited to the one performed immediately after the completion of the accumulation. For example, the release from each tank may be performed at a desired timing within a time range from the completion of the accumulation to a start of a subsequent accumulation. For example, by delaying the release from the first tank 95A until immediately before the start of the subsequent accumulation, it is possible to perform the flush supply that is substantially continuous with the release from the second tank 95B, or it is possible to perform the release from each tank simultaneously.

<Second Step of Film-Forming Process, Step S4>

In the second step of the film-forming process, the second valves 97A and 97B of the first gas supply pipe 47 and the valve 55 of the first carrier gas supply pipe 53 are closed to stop the supply of the source gas and the supply of the carrier gas. With the valve 67 of the gas exhaust pipe 66 open, the process furnace 29 is exhausted to 20 Pa or less by the vacuum pump 68 to remove (discharge) a residual source gas from the process chamber 2. In the step S4, by supplying the inert gas (for example, the N₂ gas serving as the carrier gas) to the process furnace 29, it is possible to further improve an efficiency of removing the residual source gas from the process chamber 2.

<Third Step of Film-Forming Process, Step S5>

In the third step of the film-forming process, the nitrogen-containing gas and the carrier gas are supplied. First, the valve 59 provided in the second gas supply pipe 48 and the valve 63 provided in the second carrier gas supply pipe 61 are both opened. Then, the nitrogen-containing gas whose flow rate is adjusted by the third MFC 58 and supplied through the second gas supply pipe 48 and the carrier gas whose flow rate is adjusted by the fourth MFC 62 and supplied through the second carrier gas supply pipe 61 are mixed. The mixed gas of the nitrogen-containing gas and the carrier gas is supplied into the process chamber 2 through the plurality of second gas supply holes 65 of the second nozzle 64, and is exhausted through the gas exhaust pipe 66. By supplying the nitrogen-containing gas, a silicon-containing film formed on a base film of the wafer 31 in the step S3 reacts with the nitrogen-containing gas to form the SiN film on the wafer 31.

<Fourth Step of Film-Forming Process, Step S6>

In the fourth step of the film-forming process, after the SiN film is formed on the wafer 31, the valve 59 and the valve 63 are closed, and the inner atmosphere of the process chamber 2 is vacuum-exhausted by the vacuum pump 68 to remove the nitrogen-containing gas remaining in the process chamber 2 after contributing to the formation of the SiN film. In the step S6, by supplying the inert gas (for example, the N₂ gas serving as the carrier gas) to the process chamber 2, it is possible to further improve an efficiency of removing the nitrogen-containing gas remaining in the process chamber 2 from the process chamber 2.

Then, by performing the cycle including the first step of the film-forming process through the fourth step of the film-forming process a predetermined number of times in a step S7 shown in FIG. 6, the SiN film of a predetermined thickness is formed on the wafer 31. According to the present embodiments, the cycle of the film-forming process is repeatedly performed a plurality of times.

After the film-forming process described above is completed, in a step S8 shown in FIG. 6, the inner pressure of the process chamber 2 is returned to the normal pressure (atmospheric pressure). Specifically, for example, the inert gas such as the N₂ gas is supplied into the process chamber 2 and exhausted out of the process chamber 2. As a result, the inner atmosphere of the process chamber 2 is purged with the inert gas, and a substance such as a residual gas remaining in the process chamber 2 is removed from the process chamber 2 (purging by the inert gas). Thereafter, the inner atmosphere of the process chamber 2 is replaced with the inert gas (substitution by the inert gas), and the inner pressure of the process chamber 2 is returned to the normal pressure (atmospheric pressure) (returning to the atmospheric pressure). Then, wafer (substrate) 31 is transferred out of the process chamber 2 in a step S9 shown in FIG. 6. Thereby, the substrate processing according to the present embodiment is completed.

### Effects According to Present Embodiments

According to the present embodiments, the flow rate of the source gas accumulated in each of the first tank 95A and the second tank 95B is controlled to a predetermined value by the first MFC 100. As a result, it is possible to accumulate an accurate amount of the source in each of the first tank 95A and the second tank 95B. Therefore, even when the source gas is repeatedly supplied to the process chamber 2, a deviation between the amounts of the source gas hardly occurs, and it is possible to easily maintain the amount of the source gas constant. As a result, it is possible to improve the step coverage and a reproducibility of the film formed on the surface of the substrate (that is, the wafer 31). Thereby, it is possible to improve a film thickness uniformity on the surface of the substrate and between the plurality of substrates (that is, the wafers 31). In particular, it is preferable that, even when a gas whose vapor pressure is low is used, it is possible to release the gas with an accurate and high flow velocity of the flush flow.

According to the present embodiments, since two tanks are used, it is possible to release almost the entire source gas accumulated in one tank between the release of the source gas accumulated in the other tank and the accumulation of the source gas into the other tank. In other words, in the flush supply of the source gas using the two tanks alternately, the vaporizer 91 continues to provide a vaporized gas (that is, the source gas) to one of the two tanks without waiting for the release of the source gas accumulated in the other of the two tanks to be completed. Thereby, the vaporizer 91 can be utilized to the maximum extent. By emptying the tanks (that is, by adjusting the inner pressure of each of the tanks substantially equal to the inner pressure of the process chamber 2), the vaporizer 91 is operated continuously. Thereby, it is possible to suppress the generation of substances such as particles in the gas vaporized by the vaporizer 91. As described above, as compared with a case where a single tank is used alone, it is possible to stably accumulate and release the source gas. In addition, by expanding a capacity of a vaporization tank in the vaporizer 91, or by increasing the number of the control valve 102 from one to two, or by increasing a diameter of the orifice 107 of the flow path, it is possible to further increase the flow rate of the flush supply.

According to the present embodiments, the accumulation time of the source gas is determined by the time for the source gas to reach the predetermined accumulation amount at the constant flow rate. Therefore, it is possible to more appropriately control the accumulation of the source gas into each of the first tank 95A and the second tank 95B and the release of the source gas from each of the first tank 95A and the second tank 95B. As a result, it is possible to ensure the quality of the wafer 31.

According to the present embodiments, the source gas is released (or ejected) into the process chamber 2 in the decompressed state through the first nozzle 56. Therefore, it is possible to supply the source gas using the flush supply such that the film thickness uniformity on the surface of the substrate and between the plurality of substrates can be improved.

According to the present embodiments, the first MFC 100 is commonly used for the two tanks. Therefore, it is possible to omit a preparation of a plurality of first MFCs including the first MFC 100, and also possible to simplify a structure of the substrate processing apparatus.

According to the present embodiments, the source gas alone is supplied to the first tank 95A and the second tank 95B without supplying the reactive gas. By flush supplying the source gas alone without mixing with the reactive gas, the source gas can be smoothly adsorbed on the surface of the wafer 31.

According to the present embodiments, it is possible to easily maintain the flow rate of the source gas in each of the first tank 95A and the second tank 95B constant with respect to the pressure change in the vaporizer 91 by the first MFC 100 of a pressure control type MFC. Therefore, it is possible to more accurately control the flow rate of the source gas.

According to the present embodiments, it is possible to maintain the inner pressure of each tank at the pressure value that satisfies the choked flow condition in the orifice 107 in the first MFC 100. Therefore, the accumulation time and the flush period of the source gas in each of the first tank 95A and the second tank 95B can be maintained constant more reliably.

### Other Embodiments

While the technique of the present disclosure is described in detail by way of the embodiments described above, the above-described technique is not limited thereto. The above-described technique may be modified in various ways without departing from the scope thereof.

For example, the above-described embodiments are described by way of an example in which the single vaporizer 91 and the single mass flow controller (that is, the first MFC 100) are provided in the substrate processing apparatus. However, the above-described technique is not limited thereto. For example, although not shown, the above-described technique may also be preferably applied when N number of vaporizers (N is a natural number equal to or greater than 2) and a plurality of mass flow controllers are provided in parallel with one another in a manner corresponding to N number of tanks. Further, the controller according to the technique may be configured such that, by controlling a plurality of vaporizers and a plurality of mass flow controllers to operate in coordination with each other, it is possible to ensure the flow rate of the source gas required for accumulating the amount of the source gas into each tank for performing a single flush supply within a length of time equal to N times of the flush period. It is possible to more smoothly perform the flush supply of the source gas by the coordinated operations of the plurality of vaporizers and the plurality of mass flow controllers provided in parallel.

For example, the above-described embodiments are described by way of an example in which, by performing the film-forming process by the substrate processing apparatus, the SiN film is formed on the wafer 31 by alternately supplying the source gas serving as the source (liquid source) and the nitrogen-containing gas serving as the reactant (reactive gas). However, the above-described technique is not limited thereto.

For example, at least one among nitrous oxide (N₂O) gas, nitric oxide (NO) gas, nitrogen dioxide (NO₂) gas and ammonia (NH₃) gas may be used as the nitrogen-containing gas.

For example, the reactant is not limited to the nitrogen-containing gas. A film of a different type may be formed by using other film-forming gases that react with the liquid source. In addition, three or more process gases may be used to perform the film-forming process.

For example, the above-described embodiments are described by way of an example in which the film-forming process of the semiconductor device is performed as the substrate processing of the substrate processing apparatus. However, the above-described technique is not limited thereto. The above-described technique may be applied to processes in which an object to be processed provided with a pattern whose aspect ratio is high (that is, a pattern with greater depth than width) is exposed to the vaporized gas. That is, in addition to the film-forming process described in the embodiments or instead of the film-forming process described in the embodiments, the above-described technique may be applied to a process such as a process of forming an oxide film, a process of forming a nitride film, and a process of forming a film containing a metal. The above-described technique may be suitably applied to achieve the step coverage of 90% or more for the object to be processed whose aspect ratio is 100 or more. For example, the specific contents of the substrate processing are not limited to those exemplified in the embodiments. For example, in addition to the film-forming process described in the embodiments or instead of the film-forming process described in the embodiments, the above-described technique may be applied to other substrate processing (process) such as an annealing process, an oxidation process, a nitridation process, a diffusion process and a lithography process.

The above-described technique may also be applied to other substrate processing apparatuses such as an annealing apparatus, an oxidation apparatus, a nitridation apparatus, an exposure apparatus, a coating apparatus, a drying apparatus, a heating apparatus, an apparatus using the plasma and combinations thereof.

The above-described embodiments are described by way of an example in which the manufacturing process of the semiconductor device is performed. However, the above-described technique is not limited thereto. For example, the above-described technique may be applied to a substrate processing such as a manufacturing process of a liquid crystal device, a manufacturing process of a solar cell, a manufacturing process of a light emitting device, a processing of a glass substrate, a processing of a ceramic substrate and a processing of a conductive substrate.

The above-described technique may also be applied when a constituent of one of the above-described examples is substituted with another constituent of other examples, or when a constituent of one of the above-described examples is added by another constituent of other examples. The above-described technique may also be applied when the constituent of the examples is omitted or substituted, or when a constituent added to the examples.

The above-described embodiments are described by way of an example in which the N₂ gas is used as the inert gas. However, the above-described technique is not limited thereto. For example, the above-described technique may be applied when a rare gas such as argon (Ar) gas, helium (He) gas, neon (Ne) gas and xenon (Xe) gas is used as the inert gas instead of the N₂ gas. However, in such a case, it is preferable to prepare a rare gas source. Further, it is preferable to connect the rare gas source to the first gas supply pipe 47 such that the rare gas can be introduced.

As described above, according to some embodiments in the present disclosure, it is possible to improve the film thickness uniformity of the film on the surface of the substrate and between the plurality of substrates.

What is claimed is:

1. A substrate processing apparatus comprising:
a vaporizer configured to generate a source gas by vaporizing a liquid source supplied thereto;
a tank in which the source gas ejected from the vaporizer is stored;
a flow controller provided at a pipe connecting the vaporizer with the tank and configured to control a flow rate of the source gas supplied to the tank;
a first valve provided at the pipe to open and close a flow path of the pipe;
a second valve provided downstream of the tank to release the source gas accumulated in the tank;
a process chamber provided downstream of the second valve and to which the source gas is supplied; and
a controller configured to be capable of controlling the first valve and the second valve so as to alternately and repeatedly perform an accumulation of the source gas from the vaporizer into the tank and a release of the source gas from the tank to the process chamber.

2. The substrate processing apparatus of claim 1, further comprising:
a plurality of tanks comprising the tank wherein the source gas ejected from the vaporizer is stored in the plurality of the tanks;
a plurality of first valves comprising the first valve, and provided at a plurality of pipes respectively corresponding to the plurality of the tanks to open and close a flow path of each of the pipes; and
a plurality of second valves comprising the second valve, and provided downstream of the plurality of tanks in a manner respectively corresponding to the plurality of the tanks to release the source gas accumulated in the plurality of the tanks,
wherein the accumulation of the source gas and the release of the source gas are alternately or cyclically performed using the plurality of the tanks.

3. The substrate processing apparatus of claim 1, wherein the flow controller comprises a mass flow controller, and
an accumulation time of the source gas in the tank is determined by a time for an accumulation amount of the source gas to reach a predetermined amount at a constant flow rate.

4. The substrate processing apparatus of claim 2, wherein the flow controller comprises a mass flow controller, and
an accumulation time of the source gas in each of the tanks is determined by a time for an accumulation amount of the source gas to reach a predetermined amount at a constant flow rate.

5. The substrate processing apparatus of claim 1, further comprising
a nozzle provided in the process chamber and through which the source gas released via the second valve is ejected into the process chamber in a decompressed state,
wherein the source gas accumulated in the tank is flush supplied into the process chamber through the nozzle in a time shorter than an accumulation time for the source gas to have been accumulated in the tank.

6. The substrate processing apparatus of claim 2, wherein the flow controller is commonly used for each of the tanks

7. The substrate processing apparatus of claim 2, further comprising:
a plurality of vaporizers comprising the vaporizer, and configured to generate the source gas by vaporizing the liquid source supplied thereto; and
a plurality of flow controllers comprising the flow controller, connecting the plurality of the vaporizers with the plurality of the tanks, and configured to control flow rates of the source gas supplied to the plurality of the tanks,
wherein number of the vaporizers is equal to N, number of the flow controllers is equal to N, and the plurality of the vaporizers are arranged in parallel with the plurality of the flow controllers (wherein N is a natural number equal to or greater than two), and
the controller is further configured to ensure the flow rate of the source gas for a specified amount of the source gas to be accumulated in each of the tanks within a specified length of time by operating the plurality of the vaporizers in coordination with the plurality of the flow controller, wherein the specified amount of the source gas is equal to an amount for the source gas to be released a single time, and the specified length of time is equal to N times of a single flush period.

8. The substrate processing apparatus of claim 2, wherein the vaporizer is configured to supply the source gas to the plurality of the tanks without supplying a carrier gas.

9. The substrate processing apparatus of claim 5, wherein the source gas is released into the process chamber though the nozzle without supplying a carrier gas through the nozzle for a predetermined time.

10. The substrate processing apparatus of claim 2, wherein the controller is further configured to adjust the release of the source gas such that the source gas is released from the plurality of the tanks to the process chamber at a certain timing within a time range from a completion of the accumulation of the source gas into the tank to a start of a subsequent accumulation of the source gas into the tank.

11. The substrate processing apparatus of claim 2, wherein a wafer whose aspect ratio is 100 or more is accommodated in the process chamber, and the wafer is processed by being exposed to the source gas.

12. The substrate processing apparatus of claim 2, wherein a cross-sectional area of the flow path of each of the pipes connecting the plurality of the vaporizers with the plurality of the tanks is equal to or greater than a cross-sectional area of a flow path of a pipe connecting each of the tanks with a nozzle.

13. The substrate processing apparatus of claim 2, further comprising a nozzle provided in the process chamber and through which the source gas alternately or cyclically released from each of the tanks is ejected into the process chamber in a decompressed state,
wherein the nozzle allows the source gas released from each of the tanks to form a substantially same flow in the process chamber.

14. The substrate processing apparatus of claim 2, wherein the flow controller is configured to perform a pressure control utilizing a choked flow in an orifice, and is capable of maintaining the flow rate of the source gas to each of the tanks constant with respect to a pressure change in the vaporizer.

15. The substrate processing apparatus of claim 2, wherein an accumulation time and a flush period of the source gas in the tank and a flush period thereof are controlled such that an inner pressure of each of the tanks maintains a pressure value that satisfies a choked flow condition in an orifice in the flow controller.

16. A method of manufacturing a semiconductor device, comprising:
(a) generating a source gas by a vaporizer by vaporizing a liquid source supplied thereto;
(b) accumulating the source gas into a tank by opening a first valve provided at a pipe connecting the vaporizer with the tank while controlling a flow rate of the source gas supplied to the tank by a flow controller provided at the pipe;
(c) supplying the source gas to a process chamber provided downstream of a second valve by opening the second valve provided downstream of the tank; and
(d) controlling the first valve and the second valve so as to alternately and repeatedly perform an accumulation of the source gas from the vaporizer into the tank and a release of the source gas from the tank to the process chamber.

17. A non-transitory tangible medium storing a program that causes, by a computer, a substrate processing apparatus to perform:
(a) generating a source gas by a vaporizer by vaporizing a liquid source supplied thereto;
(b) accumulating the source gas into a tank by opening a first valve provided at a pipe connecting the vaporizer with the tank while controlling a flow rate of the source gas supplied to the tank by a flow controller provided at the pipe;
(c) supplying the source gas to a process chamber provided downstream of a second valve by opening the second valve provided downstream of the tank; and
(d) controlling the first valve and the second valve so as to alternately and repeatedly perform an accumulation of the source gas from the vaporizer into the tank and a release of the source gas from the tank to the process chamber.
